(19) United States
(12) Patent Application Publication
(10) Pub. No.: US 2021/0399062 A1
(43) Pub. Date: Dec. 23, 2021

(54) DISPLAY SUBSTRATE MOTHERBOARD AND FABRICATING METHOD THEREOF, AND DISPLAY SUBSTRATE

(71) Applicant: Shenzhen China Star Optoelectronics Semiconductor Display Technology Co., Ltd., Shenzhen (CN)

(72) Inventors: Zhibin HAN, Shenzhen, Guangdong (CN); Xiaodong ZHANG, Shenzhen, Guangdong (CN); Xiang XIAO, Shenzhen, Guangdong (CN); Kuo GAO, Shenzhen, Guangdong (CN)

(21) Appl. No.: 16/961,862

(22) PCT Filed: Jul. 2, 2020
(86) PCT No.: PCT/CN2020/099948

§ 371 Date: Jul. 13, 2020

(30) Foreign Application Priority Data
Jun. 17, 2020 (CN) 202010552411.7

(51) Int. Cl. H01L 27/32

(52) U.S. Cl. CPC H01L 27/3218; H01L 27/3246; H01L 27/3276

(57) ABSTRACT

A display substrate motherboard and a fabricating method thereof, and a display substrate are provided. The display substrate motherboard has first display substrates and second display substrates. A long axis of the second display substrates is parallel to a first direction, a long axis of the first display substrates is parallel to a second direction, and the first direction is perpendicular to the second direction. A long axis of sub-pixels on the first display substrates is parallel to a short axis of the first display substrate, and a long axis of sub-pixels on the second display substrates is parallel to a short axis of the second display substrate.

### FIELD OF DISCLOSURE

The present application relates to displays, and more particularly to a display substrate motherboard and a fabricating method thereof, and a display substrate.

### BACKGROUND OF DISCLOSURE

Organic light-emitting diode (OLED) displays have gradually become high-end displays that replace liquid crystals due to their advantages such as ultra-high contrast, wide color gamut, fast response, and active light emission. As a size of OLED displays and OLED TVs continues to increase, the size of their corresponding mass-produced glass substrates also continues to increase. In order to maximize a utilization of glass, OLED products of different sizes need to be fabricated on a same glass substrate, that is, mixed arrangement (multi model glass; MMG). In this mixed arrangement method, when two OLED panels with different sizes are arranged in different directions (vertical), a linear (line-bank) printing method of luminous ink is restricted. After printing a product's OLED panel, it is required to rotate a glass substrate 90 degrees and then to print the OLED panel of another product. This leads to an increase in equipment costs and an increase in production time, which is disadvantageous for mass production.

Therefore, the conventional technology has defects and needs to be solved urgently.

### SUMMARY OF DISCLOSURE

The present application provides a display substrate motherboard and a fabricating method thereof, and a display substrate, which can solve a technical problem that an equipment cost and production time increase when different size OLED products (i.e. display substrates) on the display substrate mother board are in a mixed arrangement.

To solve the above problems, technical solutions provided in this application are as follows:

The present application provides a display substrate motherboard comprising: first display substrates and second display substrates, at least two of the first display substrates spaced apart along a first direction;
at least two of the second display substrates spaced apart along a second direction, wherein the first display substrates are located on at
at least one side of the second display substrates in the second direction, and the first direction and the second direction are perpendicular to each other; and
a long axis of the first display substrates being parallel to the second direction, and a long axis of the second display substrate being parallel to the first direction,
wherein a long axis of sub-pixels on the first display substrates is parallel to a short axis of the first display substrates, a long axis of sub-pixels on the second display substrates is parallel to a short axis of the second display substrates, and the sub-pixels with a same color on the first display substrates and the sub-pixels with a same color on the second display substrates are spaced apart along the first direction.

In the display substrate motherboard of the present application, a first sub-pixel, a second sub-pixel, and a third sub-pixel on the first display substrates are sequentially arranged along the second direction, and a first sub-pixel, a second sub-pixel, and a third sub-pixel on the second display substrates are sequentially arranged along the second direction.

In the display substrate motherboard of the present application, a pixel opening area of the sub-pixels on the first display substrates is equal to a pixel opening area of the sub-pixels on the second display substrates.

In the display substrate motherboard of the present application, a pixel opening width of the sub-pixels on the first display substrates in the first direction is equal to a pixel opening width of the sub-pixels on the second display substrate in the second direction.

In the display substrate motherboard of the present application, a size of the first display substrates is different from a size of the second display substrates.

In the display substrate motherboard of the present application, the second display substrates include scanning lines extending in the first direction and data lines extending in the second direction, wherein a row of the sub-pixels of the second display substrates in the first direction is connected to two of the scan lines, and two columns of the sub-pixels of the second display substrates in the second direction are connected to one of the data lines.

The present application further provides a fabricating method of a display substrate motherboard, wherein a motherboard base comprises a first effective region and a second effective region;

the fabricating method comprises following steps of:
a step S1 of fabricating a pixel definition layer on the motherboard base, and patterning the pixel definition layer to form sub-pixel holes corresponding to the first effective region and corresponding to the second effective region;
a step S2 of fabricating a luminescent material in a linear manner on the motherboard base in sub-pixel holes of the first effective region and sub-pixel holes of the second effective region by using nozzles arranged along a direction of rows/columns, so as to form a first luminescent material, a second luminescent material, and a third luminescent material, all of which are sequentially arranged in the second direction, wherein the first direction and the second direction are perpendicular to each other;
a step S3 of fabricating a cathode layer on the luminescent material; and
a step S4 of fabricating a thin film encapsulation layer on the cathode layer to form first display substrates corresponding to the first effective region and second display substrates corresponding to the second effective region.

In the fabricating method of the present application, in the step S1, after patterning the pixel definition layer, a pixel opening area of the sub-pixel holes corresponding to the first effective region is equal to a pixel opening area of the sub-pixel holes corresponding to the second effective region, and a pixel opening width of the sub-pixel holes in the first effective region in the first direction is equal to a pixel opening width of the sub-pixel holes in the second effective region in the second direction.

In the fabricating method of the present application, in the step S2, a luminescent material with a same color is fabricated simultaneously in the first effective region and the second effective region along the first direction by the nozzles, so as to form the luminescent material with the same color in the sub-pixel holes in the first direction.

In the fabricating method of the present application, a size of the first effective region is different from a size of the second effective region, and in the step S1, a long axis of the sub-pixel holes formed in the first effective region is parallel to a short axis of the first effective region, and a long axis of the sub-pixel holes formed in the second effective region is parallel to a short axis of the second effective region.

The present application further provides a display substrate, comprising:
a base;
an array driving layer disposed on the base and comprising scan lines extending in a first direction and data lines extending in a second direction, wherein the first direction is perpendicular to the second direction;
a luminescent device layer disposed on the array driving layer; and
a thin film encapsulation layer disposed on the light emitting device layer;
wherein the display substrate comprises sub-pixels distributed in an array, and the sub-pixels in the first direction have a same color; and
wherein a row of the sub-pixels of the display substrate in the first direction is connected to two of the scan lines, and two rows of the sub-pixels in the second direction are connected to one of the data lines.

In the display substrate of the present application, number of the data lines of the display substrate is less than number of the scan lines.

In the display substrate of the present application,

In the display substrate of the present application,

In the display substrate of the present application, flip-chip films are arranged in a one-dimensional array and bound to a corresponding non-display region of the display substrate, and one of the data lines is correspondingly connected to one of the flip-chip films.

In the display substrate of the present application, the luminescent device layer comprises: anodes; and anode repair bridges disposed on a same layer as the anodes, wherein the anodes are electrically connected to a pixel driving circuit in the array driving layer through contact holes.

In the display substrate of the present application, the anode repair bridges are formed by extending the anodes, and the anode repair bridges corresponding to two adjacent sub-pixels with a same color are disposed oppositely and staggered.

In the display substrate of the present application, the anode repair bridges are in a same layer as the anodes and are insulated with each other, and one of the anode repair bridges is located between the anodes corresponding to two adjacent sub-pixels with a same color.

In the display substrate of the present application, two sub-pixels with a same color are provided in a region surrounded by two adjacent data lines and two adjacent scan lines.

Beneficial effects of this application are that: the display substrate motherboard and a fabricating method thereof, and a display substrate provided in the present application are provided by setting a long axis of the sub-pixels on the first display substrates parallel to a short axis of the first display substrates, and by setting a long axis of the sub-pixels on the second display substrates parallel to a short axis of the second display substrates, such that the display substrates with different sizes arranged on the display substrate motherboard can achieve a purpose of simultaneously printing an luminescent ink in a linear manner, thereby reducing an equipment cost and production time, which is beneficial to the mass production of products.

### DESCRIPTION OF DRAWINGS

The following detailed description of specific embodiments of the present application will make technical solutions and other beneficial effects of the present application obvious in conjunction with the accompanying drawings.

FIG. 1 is a schematic structural diagram of a display substrate motherboard according to an embodiment of the present application;

FIG. 2 is a flowchart of a fabricating method of a display substrate motherboard according to an embodiment of the present application;

FIG. 3 is a schematic diagram of a pixel definition layer on a mother substrate after patterning according to an embodiment of the present application;

FIG. 4 is a schematic diagram of fabricating a luminescent material on a motherboard base according to an embodiment of the present application;

FIG. 5 is a schematic diagram of nozzles disposed along a row/column direction according to y an embodiment of the present application;

FIG. 6 is a schematic diagram of a film-layer structure of a display substrate according to an embodiment of the present application;

FIG. 7 is a schematic structural diagram of a display substrate according to an embodiment of the present application;

FIG. 8 is a schematic diagram of an anode of a display substrate according to an embodiment of the present application;

FIG. 9 is a schematic diagram of an anode of another display substrate according to an embodiment of the present application;

FIG. 10 is a flowchart of a defect repair method for a display substrate according to an embodiment of the present application; and

FIG. 11 is a schematic diagram of a pixel repair circuit of a display substrate provided by the present application.

### DETAILED DESCRIPTION OF PREFERRED EMBODIMENTS

Technical solutions in the embodiments of the present application will be clearly and completely described below with reference to the drawings in the embodiments of the present application. Obviously, the described embodiments are only a part of the embodiments of the present application, but not all the embodiments. Based on the embodiments in the present application, all other embodiments obtained by those skilled in the art without creative work fall into the protection scope of the present application.

In the description of this application, it is understood that orientation or positional relationships indicated by terms of “longitudinal”, “horizontal”, “length”, “width”, “top”, “bottom”, “front”, “back”, “left”, “right”, “vertical”, “horizontal”, etc., are based on the orientation or position relationship shown in the figure. It is only for the convenience of describing this application and simplifying the description, and does not indicate or imply that the device or element referred to must have a specific orientation, be constructed and operate in a specific orientation, and therefore cannot be understood as a limitation on this application. In addition, the terms of “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless specifically defined otherwise. In this application, “/” means “or”.

This application may repeat reference numerals and/or reference letters in different examples, and such repetition is for simplicity and clarity, and does not itself indicate a relationship between the various embodiments and/or settings discussed.

In a traditional display substrate motherboard, when two display substrates of different sizes are arranged in a mixed manner, that is, when arrangement direction of a long axis (or a long side) of two display substrates with different sizes are perpendicular to each other, since a pixel arrangement of the display substrate is generally that a direction of the long axis (or the long side) of the sub-pixels is parallel to a direction of the short axis (or the short side) of the display substrate, the pixel arrangement directions of two display substrates of different sizes are induced to be perpendicular to each other. Therefore, a linear (line-bank) printing method for printing luminescent inks/materials is limited. It is required to rotate a display substrate motherboard 90 degrees and then to print a display substrate with another size. This leads to an increase in equipment costs and an increase in production time, which is disadvantageous for mass production.

In this application, a display substrate pixel arrangement design using a line-bank printing method is provided. In a case of mixed arrangement of display substrates with different sizes, it is possible to directly print display substrates with different sizes without rotating the display substrate motherboard. It does not increase equipment and time costs, and is suitable for mass production.

Hereinafter, the display substrate mother board of the present application will be described in detail in combination with specific embodiments.

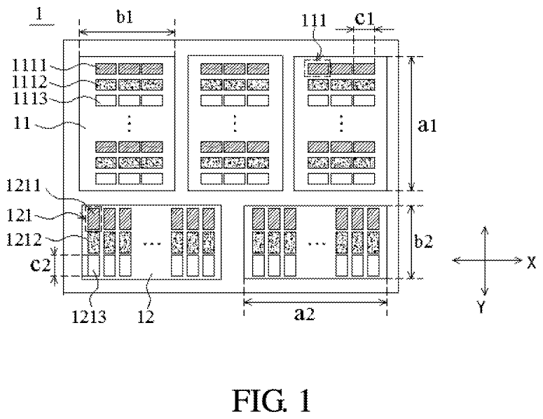

Refer to FIG. 1, which is a schematic structural diagram of a display substrate motherboard according to an embodiment of the present application. The display substrate motherboard 1 comprises first display substrates 11 and second display substrates 12. At least two of the first display substrates 11 are spaced apart along a first direction X. At least two of the second display substrates 12 are spaced apart along a second direction Y, wherein the first display substrates 11 are located on at least one side of the second display substrates 12 in the second direction Y, and the first direction X and the second direction Y are perpendicular to each other.

A size of the first display substrates 11 is different from a size of the second display substrates 12. In this embodiment, the size of the first display substrates 11 is 65″8K, and the size of the second display substrates 12 is 55″4K. Of course, it is not limited to this.

It can be understood that the first display substrates 11 and the second display substrates 12 may be provided in multiple rows in the second direction Y. This embodiment is described by using the first display substrates 11 on a side of the second display substrates 12 in the second direction Y as an example.

An arrangement of the first display substrates 11 and the second display substrates 12 on the display substrate motherboard 1 is that: a long axis a1 of the first display substrates 11 is parallel to the second direction Y, and a long axis a2 of the second display substrates 12 is parallel to the first direction X. That is, two display substrates with different sizes are arranged perpendicular to each other.

A long axis c1 of sub-pixels 111 on the first display substrates 11 is parallel to a short axis b1 of the first display substrates 11, a long axis c2 of sub-pixels 121 on the second display substrates 12 is parallel to a short axis b2 of the second display substrates 12, and the sub-pixels with a same color on the first display substrates 11 and the sub-pixels with a same color on the second display substrates 12 are spaced apart along the first direction X.

A first sub-pixel 1111, a second sub-pixel 1112, and a third sub-pixel 1113 on the first display substrates 11 are sequentially arranged along the second direction Y, and a first sub-pixel 1211, a second sub-pixel 1212, and a third sub-pixel 1213 on the second display substrates 12 are sequentially arranged along the second direction Y.

In an embodiment, a pixel opening area of the sub-pixels 111 on the first display substrates 11 is equal to a pixel opening area of the sub-pixels 121 on the second display substrate 12.

Further, a pixel opening width of the sub-pixels 111 on the first display substrates 11 in the first direction X is equal to a pixel opening width of the sub-pixels 121 on the second display substrate 12 in the second direction Y.

This embodiment does not specifically limit film layers and component structures of the first display substrate 11, and may be a conventional OLED panel structure. The second display substrates 12 include scanning lines extending in the first direction X and data lines extending in the second direction Y, wherein a row of the sub-pixels 121 of the second display substrates 12 in the first direction X is connected to two of the scan lines, and two columns of the sub-pixels 121 of the second display substrates 12 in the second direction Y are connected to one of the data lines. A structural design of the second display substrates 12 is not described in detail here. For details, refer to following description of the structure of the display substrate.

The display substrate motherboard of the present application is designed in a manner described above, and the display substrates with different sizes can be used for line-bank printing at the same time when the display substrates with different sizes are arranged in a mixed manner. Display substrates with different sizes can be directly printed without rotating the display substrate motherboard. Therefore, it does not increase equipment and time costs and is suitable for mass production.

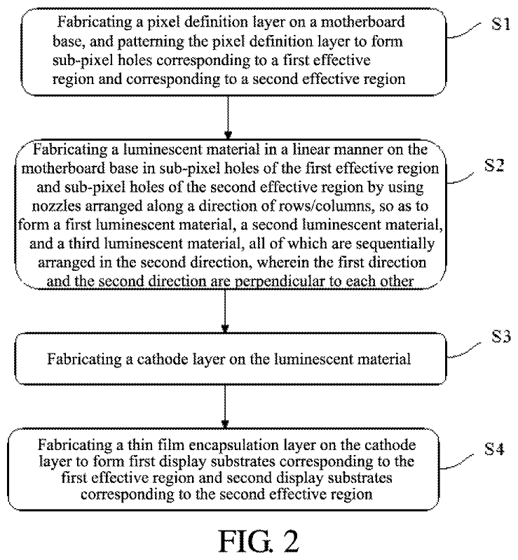

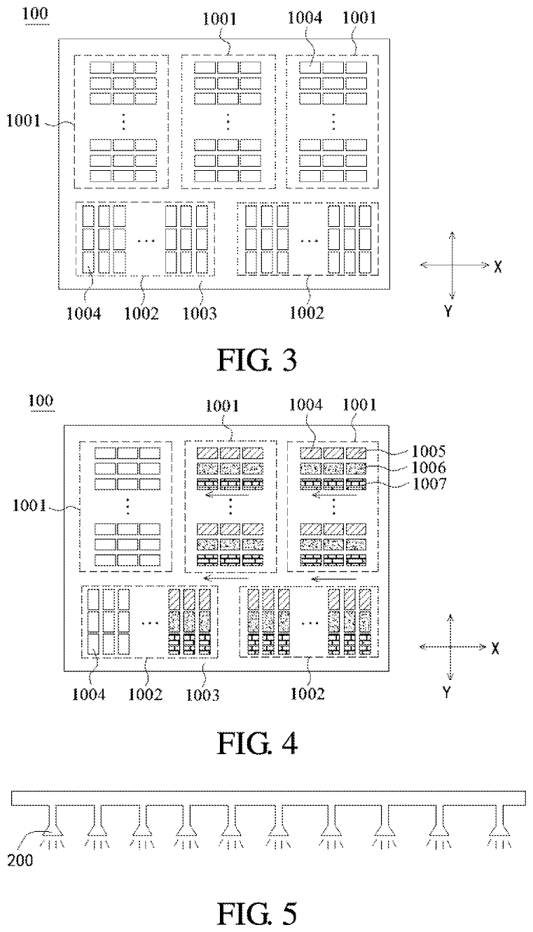

The present application also provides a fabricating method of the above display substrate motherboard, as shown in FIG. 2 together with FIG. 3, a motherboard base 100 is provided, and the mother substrate 100 includes a first effective region 1001 and a second effective region 1002. The motherboard base 100 may be an array driving substrate. That is, the motherboard base 100 is provided with: an array drive circuit corresponding to the first effective region 1001 and the second effective region 1002; and an anode electrically connected to the array drive circuit.

The method comprises following steps.

In a step S1, as shown in FIG. 3, a pixel definition layer 103 is fabricated on the motherboard base 100, and the pixel definition layer 1003 is patterned to form sub-pixel holes 1004 corresponding to the first effective region 1001 and corresponding to the second effective region 1002.

In the step S1, after patterning the pixel definition layer 1003, a pixel opening area of the sub-pixel holes 1004 corresponding to the first effective region 1001 is equal to a pixel opening area of the sub-pixel holes 1004 corresponding to the second effective region 1002, and a pixel opening width of the sub-pixel holes 1004 in the first effective region 1001 in the first direction X is equal to a pixel opening width of the sub-pixel holes 1004 in the second effective region 1002 in the second direction Y.

In the present embodiment, a size of the first effective region 1001 is different from a size of the second effective region 1002. It can be understood that the first effective region 1001 and the second effective region 1002 respectively correspond to display substrates with different sizes.

In the step S1, a long axis (i.e. a long side) of the sub-pixel holes 1004 formed in the first effective region 1001 is parallel to a short axis (i.e. a short side) of the first effective region 1001, and a long axis of the sub-pixel holes 1004 formed in the second effective region 1002 is parallel to a short axis of the second effective region 1002.

In a step S2, as shown in FIG. 4, a luminescent material is fabricated in a linear manner on the motherboard base 100 in sub-pixel holes of the first effective region 1001 and sub-pixel holes of the second effective region 1002 by using nozzles arranged along a direction of rows/columns, so as to form a first luminescent material 1005, a second luminescent material 1006, and a third luminescent material 1007, all of which are sequentially arranged in the second direction Y, wherein the first direction X and the second direction Y are perpendicular to each other.

With reference to FIG. 5, FIG. 5 is a schematic diagram of nozzles provided along the row/column direction provided by the embodiment of the present application. In FIG. 5, only one row of nozzles on an inkjet printing device is taken as an example, one nozzle 200 corresponds to one sub-pixel hole 1004, it can be understood that multiple sets of the nozzles 200 may be provided on the inkjet printing device.

In the step S2, a luminescent material with a same color is fabricated simultaneously in the first effective region 1001 and the second effective region 1002 along the first direction X by the nozzles, so as to form the luminescent material with the same color in the sub-pixel holes 1004 in the first direction X.

The display substrate motherboard is designed in a manner described above, and the display substrates with different sizes can be used for line-bank printing at the same time when the display substrates with different sizes are arranged in a mixed manner. Display substrates with different sizes can be directly printed without rotating the display substrate motherboard.

In a step S3, a cathode layer is fabricated on the luminescent material.

In a step S4, a thin film encapsulation layer is fabricated on the cathode layer to form first display substrates corresponding to the first effective region and second display substrates corresponding to the second effective region.

Using the above method, a display substrate motherboard with different sizes can be fabricated. The display substrate motherboard is provided with cutting lanes, and the cutting lanes are respectively arranged around the first effective region and the second effective region. Multiple first display substrates and multiple second display substrates can be obtained by cutting the fabricated display substrate motherboard along the cutting lanes.

Another object of the present application is to provide a display substrate that provides optimized space for components such as capacitors, thin-film transistors, and the like, while facilitating high pixel density design to achieve high resolution of the substrate.

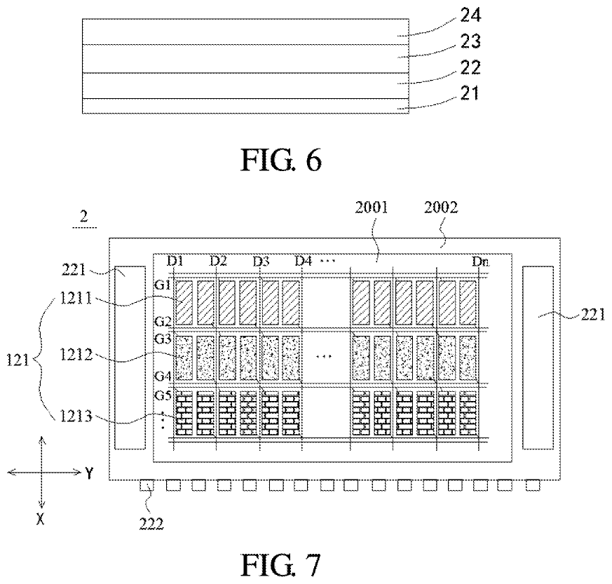

As shown in FIG. 6, FIG. 6 is display substrates formed by cutting the above-mentioned display substrate motherboard, which includes a base 21, an array driving layer 22, a luminescent device layer 23, and a thin film encapsulation layer 24, all of which are layer-stacked. The array driving layer 22 is disposed on the base 21; the luminescent device layer 23 is disposed on the array driving layer 22; and the thin film encapsulation layer 24 is disposed on the luminescent device layer 23.

The base 21 may be a glass substrate or a flexible substrate.

It can be understood that the array driving layer 22 includes an inorganic stacked layer and a pixel driving circuit disposed in the inorganic stacked layer. The luminescent device layer 23 includes an organic stacked layer and a luminescent device provided in the organic stacked layer. The light emitting device includes an anode, a luminescent layer, and a cathode layer, all of which are layer-stacked.

As shown in FIG. 7, it is a schematic structural diagram of a display substrate provided by an embodiment of the present application. It should be noted that the display substrate 2 is the second display substrate 12 formed by cutting the display substrate motherboard. The display substrate 2 includes a display region 2001 and a non-display region 2002. The display region 2001 includes scan lines G (i.e., G1, G2 . . .) extending in the first direction X ana data lines D (i.e., D1, D2 . . .) extending in the second direction Y. The first direction X is perpendicular to the second direction Y. The display substrate 2 further includes sub-pixels 121 distributed in an array, and colors of the sub-pixels 121 in the first direction X are the same.

The sub-pixels 121 includes a first sub-pixel 1211, a second sub-pixel 1212, and a third sub-pixel 1213. Further, the first sub-pixel 1211, the second sub-pixel 1212, and the third sub-pixel 1213 are sequentially arranged along the second direction Y. The first sub-pixel 1211, the second sub-pixel 1212, and the third sub-pixel 1213 form a pixel unit.

The display substrate of the present application can realize a compatible design of the mixed arrangement design of the display substrate motherboard and the line bank printing method. In the mixed arrangement (multi model glass; MMG) process, the display substrate of the present application can realize a horizontal line bank printing scheme and the MMG horizontal arranging scheme based on a backplane design maintaining to be compatible for the conventional design (COF is below, and GOA is on the left and right sides). The uniformity of the film thickness of the inkjet printing (IJP) process and the display quality can be improved by using a line bank printing. The utilization rate of glass substrate/motherboard substrate and the economic benefit of mass production can be improved by using MMG arrangement.

In this embodiment, a row of sub-pixels 121 in the first direction X of the display substrate is connected to the two of the scan lines G, and two columns of sub-pixels 121 in the second direction Y are connected to one of the data lines D.

Two sub-pixels with a same color are provided in a region surrounded by two adjacent data lines and two adjacent scan lines.

A gate driving circuit (GOA circuit) 221 is provided in the non-display area 2002 on both sides of the display substrate 2. The scan lines G are electrically connected to the GOA circuit 221. The GOA circuit 221 is used to provide a gate driving signal for the scan lines G. A one-dimensional array of flip-chip films (source drivers) 222 are bound to the non-display region 2002 corresponding to a bottom frame of the display substrate 2, and one of the data lines D is correspondingly connected to one of the flip-chip films 222.

A pixel design of the display substrate is half-data-two-gate (HDTG): that is, each pixel includes one RGB sub-pixel, each row of sub-pixels corresponds to two scanning lines, and each column of sub-pixels corresponds to one data line. The driving method of the display substrate is: turning on two gate driving signals at a time. For example, when driving the first row of sub-pixels, G1 and G2 are turned on at the same time, and then the first row of sub-pixels will write signals (such as red sub-pixels) through all of the data lines D1, D2 . . . Dn. When driving a second row of the sub-pixels, G3 and G4 are turned on at the same time. At this time, the second row of sub-pixels will write signals (such as green sub-pixels) through all of the data lines D1, D2 . . . Dn, and so on.

The display substrate can also reduce a space occupied by traces in the backplane, optimize the space design of capacitors and thin film transistors, and facilitate the design of high pixel density. Compared to the conventional backplane design, there are an average of 1 scan line and 3 data lines per pixel, for a total of 4 traces. In this application, the number of traces for a single sub-pixel in this application is 2 scan lines, and 1.5 data lines for three sub-pixels, for a total of 3.5 traces, which frees up the design space of 0.5 traces. Calculated with 10 um line width and 8 um sub-pixel space, a single sub-pixel freed up 4.8% of the design space. These spaces can be used to optimize the design of capacitors and thin film transistors, and are more suitable for pixel design with high pixel density.

In addition, the number of the data lines D of the display substrate is less than the number of the scan lines G. Since the number of the data lines D is halved compared to the original, the number of the flip chips 222 is also halved, so the cost is greatly reduced. The number of scan lines G has increased, but the mass production scheme uses GOA circuit design, which will not bring about an increase in material costs. Therefore, the display substrate can halve the number of the flip-chip thin film 222, greatly reducing the cost, and has a good mass production benefit.

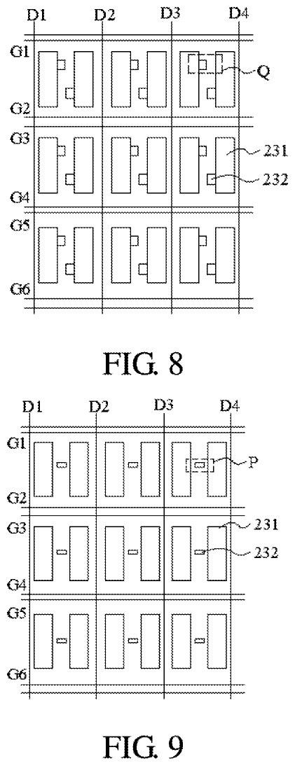

As shown in FIG. 8, it is a schematic diagram of an anode of a display substrate provided by an embodiment of the present application. The luminescent device layer 23 of the display substrate comprises: anodes 231; and anode repair bridges 232 disposed on a same layer as the anodes 231, wherein the anodes 231 are electrically connected to a pixel driving circuit in the array driving layer 22 through contact holes. The anode repair bridges 232 are formed by extending the anodes 231, and the anode repair bridges 232 corresponding to two adjacent sub-pixels with a same color are disposed oppositely and staggered.

It should be noted that there is a gap between the anode repair bridge 232 corresponding to one sub-pixel and the anode 231 and the anode repair bridge 232 corresponding to the adjacent sub-pixels. Therefore, a short circuit between two adjacent sub-pixels during normal display of the display substrate is avoided.

As shown in FIG. 9, it is a schematic diagram of an anode of another display substrate provided by an embodiment of the present application. In another embodiment, the anode repair bridges 232 are in a same layer and are insulated with each other, and one of the anode repair bridges 232 is located between the anodes 231 corresponding to two adjacent sub-pixels with a same color.

It can be understood that the anode repair bridges 232 and the anodes 231 are formed of a same material through a same photomask process.

The display substrate provided by this application can also realize pixel repair, specifically: when the adjacent sub-pixels of the same color are short-term or short-circuited during the manufacturing process, they will be cut off into floating OLED devices. The display substrate provided by the present application can electrically connect a defective sub-pixel (i.e., a floating OLED device) to a sub-pixel adjacent to the same color by laser welding, thereby causing the defective sub-pixel to emit light.

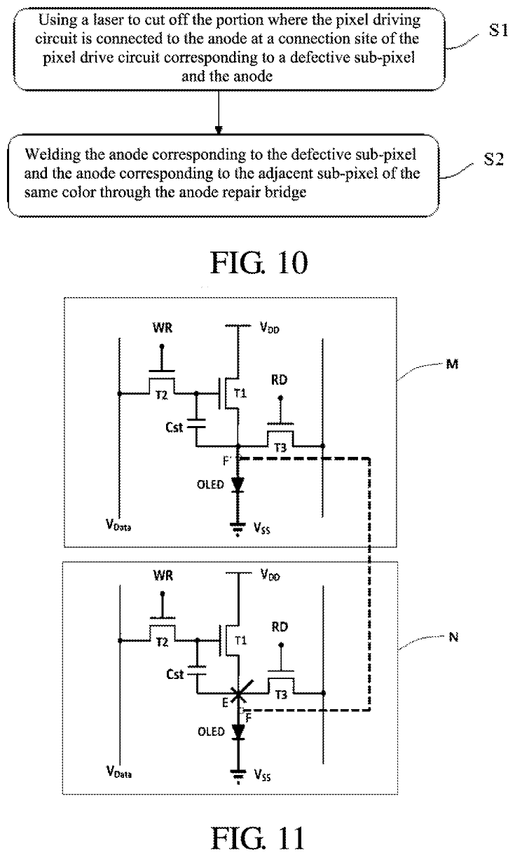

In order to achieve the above object, the present application also provides a defect repair method for the above display substrate, the anode in the light emitting device layer of the display substrate is electrically connected to the pixel driving circuit in the array driving layer, and the pixel driving circuit is used to drive the luminescent layer in the luminescent device layer to emit light. Referring to FIG. 10, the method includes the following steps:

In a step S1, a laser is used to cut off the portion where the pixel driving circuit is connected to the anode at a connection site of the pixel drive circuit corresponding to a defective sub-pixel and the anode.

Specifically, the cutting site may be at any position of the portion where the pixel driving circuit is connected to the anode, for example, the position where the cutting site is connected to the anode and the driving thin film transistor in the pixel driving circuit.

In a step S2, the anode corresponding to the defective sub-pixel and the anode corresponding to the adjacent sub-pixel of the same color are welded through the anode repair bridge.

Specifically, referring to FIG. 8, when the anode repair bridges 232 corresponding to two adjacent sub-pixels with a same color are disposed oppositely and staggered, in the step S2, a laser is used to laser the anode repair bridge on the anode corresponding to the defective sub-pixel, so that the anode repair bridge corresponding to the defective sub-pixel is welded to the anode corresponding to the adjacent sub-pixel with the same color. The repair site is shown as Q in FIG. 8.

Alternatively, in the step S2, a laser is used to laser the anode repair bridge on the anode corresponding to the defective sub-pixel, such that the anode repair bridge on the anode corresponding to the defective sub-pixel is welded to the anode repair bridge on the anode corresponding to the adjacent sub-pixel with the same color.

Referring to FIG. 9, an anode repair bridge 232 is located between the anodes 231 corresponding to two adjacent sub-pixels with the same color. At this time, in the step S2, a laser is used to laser the anode repair bridge between the defective sub-pixel and the adjacent sub-pixel with the same color, so as to weld the anode repair bridge to the anode corresponding to the defective sub-pixel and the anode corresponding to the adjacent sub-pixel with the same color. The repair site is shown as P in FIG. 9.

Please refer to FIG. 11, which is a schematic diagram of a pixel repair circuit of a display substrate provided by the present application. In FIG. 11, M is a pixel circuit of a normal sub-pixel, N is a pixel circuit of a defective sub-pixel, and M and N are pixel circuits of two sub-pixels with the same color, respectively. Here, at a cutting site of E, the anode of the defective sub-pixel and the pixel circuit are cut off at E, and the anode of the defective sub-pixel is welded to the pixel circuit adjacent to the normal sub-pixel with the same color through the anode repair bridge. Here, the pixel circuit N is connected to the F′ site in the pixel circuit M via the anode repair bridge at the F site (the repair route is shown by a dotted line in FIG. 11). At this time, the signal driving the sub-pixel in the pixel circuit M to emit light is simultaneously transmitted to the anode of the light-emitting diode OLED in the pixel circuit N, so that the defective sub-pixel emits light normally.

Since the display substrate of the present application can repair defective pixels, the life of the product is improved, and the number of defective products is reduced, thereby saving costs.

From above, although this application has been disclosed as above with preferred embodiments, the above preferred embodiments are not intended to limit this application. Those of ordinary skill in the art can make various changes and modifications without departing from the spirit and scope of this application. Therefore, the protection scope of the present application is subject to the scope defined by the claims.

1. A display substrate motherboard, comprising: first display substrates and second display substrates,
at least two of the first display substrates spaced apart along a first direction;
at least two of the second display substrates spaced apart along a second direction, wherein the first display substrates are located on at least one side of the second display substrates in the second direction, and the first direction and the second direction are perpendicular to each other; and
a long axis of the first display substrates being parallel to the second direction, and a long axis of the second display substrate being parallel to the first direction,
wherein a long axis of sub-pixels on the first display substrates is parallel to a short axis of the first display substrates, a long axis of sub-pixels on the second display substrates is parallel to a short axis of the second display substrates, and the sub-pixels with a same color on the first display substrates and the sub-pixels with a same color on the second display substrates are spaced apart along the first direction.

2. The display substrate motherboard according to claim 1, wherein a first sub-pixel, a second sub-pixel, and a third sub-pixel on the first display substrates are sequentially arranged along the second direction, and a first sub-pixel, a second sub-pixel, and a third sub-pixel on the second display substrates are sequentially arranged along the second direction.

3. The display substrate motherboard according to claim 2, wherein a pixel opening area of the sub-pixels on the first display substrates is equal to a pixel opening area of the sub-pixels on the second display substrates.

4. The display substrate motherboard according to claim 3, wherein a pixel opening width of the sub-pixels on the first display substrates in the first direction is equal to a pixel opening width of the sub-pixels on the second display substrate in the second direction.

5. The display substrate motherboard according to claim 1, wherein a size of the first display substrates is different from a size of the second display substrates.

6. The display substrate motherboard according to claim 1, wherein the second display substrates include scanning lines extending in the first direction and data lines extending in the second direction, wherein a row of the sub-pixels of the second display substrates in the first direction is connected to two of the scan lines, and two columns of the sub-pixels of the second display substrates in the second direction are connected to one of the data lines.

7. A fabricating method of a display substrate motherboard, wherein a motherboard base comprises a first effective region and a second effective region;
the fabricating method comprises following steps of:
a step S1 of fabricating a pixel definition layer on the motherboard base, and patterning the pixel definition layer to form sub-pixel holes corresponding to the first effective region and corresponding to the second effective region;
a step S2 of fabricating a luminescent material in a linear manner on the motherboard base in sub-pixel holes of the first effective region and sub-pixel holes of the second effective region by using nozzles arranged along a direction of rows/columns, so as to form a first luminescent material, a second luminescent material, and a third luminescent material, all of which are sequentially arranged in the second direction, wherein the first direction and the second direction are perpendicular to each other;
a step S3 of fabricating a cathode layer on the luminescent material; and
a step S4 of fabricating a thin film encapsulation layer on the cathode layer to form first display substrates corresponding to the first effective region and second display substrates corresponding to the second effective region.

8. The fabricating method according to claim 7, wherein, in the step S1, after patterning the pixel definition layer, a pixel opening area of the sub-pixel holes corresponding to the first effective region is equal to a pixel opening area of the sub-pixel holes corresponding to the second effective region, and a pixel opening width of the sub-pixel holes in the first effective region in the first direction is equal to a pixel opening width of the sub-pixel holes in the second effective region in the second direction.

9. The fabricating method according to claim 7, wherein, in the step S2, a luminescent material with a same color is fabricated simultaneously in the first effective region and the second effective region along the first direction by the nozzles, so as to form the luminescent material with the same color in the sub-pixel holes in the first direction.

10. The fabricating method according to claim 7, wherein a size of the first effective region is different from a size of the second effective region, and in the step S1, a long axis of the sub-pixel holes formed in the first effective region is parallel to a short axis of the first effective region, and a long axis of the sub-pixel holes formed in the second effective region is parallel to a short axis of the second effective region.

11. A display substrate, comprising:
a base;
an array driving layer disposed on the base and comprising scan lines extending in a first direction and data lines extending in a second direction, wherein the first direction is perpendicular to the second direction;
a luminescent device layer disposed on the array driving layer; and
a thin film encapsulation layer disposed on the light emitting device layer;
wherein the display substrate comprises sub-pixels distributed in an array, and the sub-pixels in the first direction have a same color; and
wherein a row of the sub-pixels of the display substrate in the first direction is connected to two of the scan lines, and two rows of the sub-pixels in the second direction are connected to one of the data lines.

12. The display substrate according to claim 11, wherein number of the data lines of the display substrate is less than number of the scan lines.

13. The display substrate according to claim 12, wherein flip-chip films are arranged in a one-dimensional array and bound to a corresponding non-display region of the display substrate, and one of the data lines is correspondingly connected to one of the flip-chip films.

14. The display substrate according to claim 11, wherein the luminescent device layer comprises: anodes; and anode repair bridges disposed on a same layer as the anodes, wherein the anodes are electrically connected to a pixel driving circuit in the array driving layer through contact holes.

15. The display substrate according to claim 14, wherein the anode repair bridges are formed by extending the anodes, and the anode repair bridges corresponding to two adjacent sub-pixels with a same color are disposed oppositely and staggered.

16. The display substrate according to claim 14, wherein the anode repair bridges are in a same layer as the anodes and are insulated with each other, and one of the anode repair bridges is located between the anodes corresponding to two adjacent sub-pixels with a same color.

17. The display substrate according to claim 11, wherein two sub-pixels with a same color are provided in a region surrounded by two adjacent data lines and two adjacent scan lines.
